(19) United States
(12) Patent Application Publication
(10) Pub. No.: US 2026/0100300 A1
(43) Pub. Date: Apr. 9, 2026

(54) RESISTOR TRIMMING STRUCTURES

(71) Applicant: GlobalFoundries U.S. Inc., Malta, NY (US)

(72) Inventors: Siddharth Gupta, Uttar Pradesh (IN); Sandeep Tripathi, Uttar Pradesh (IN); Pruthvi Muchharla Hariprasad, Bangalore (IN); Lejan Pu, San Jose, CA (US); Devesh Dwivedi, Bangalore Karnataka (IN)

(21) Appl. No.: 18/908,446

(22) Filed: Oct. 7, 2024

(51) Int. Cl. H01C 17/22; H01L 27/08

(52) U.S. Cl. CPC H01C 17/22; H10D 84/209

(57) ABSTRACT

The present disclosure relates to semiconductor structures and, more particularly, to resistor trimming structures and methods of use. The structure includes: a set of resistors each of which include an increasing resistance value; and a set of switches each of which are connected to a respective resistor of the set of resistors and each of which comprise a decreasing width dimension for each resistor of increasing resistance value.

### BACKGROUND

The present disclosure relates to semiconductor structures and, more particularly, to resistor trimming structures and methods of use.

A resistor trimming structure is a circuit comprising many resistors which are connected to switches used to calibrate and fine tune circuits. In known resistor trimming structures, the resistors are arranged in series, e.g., in a ladder format, with increasing resistance value, e.g., by a multiple of two (2), that are turned on and off by a switch of constant width. For example, with a bottommost resistor of 50 Ohms, the next resistors will be 100 Ohms, 200 Ohms, 400 Ohms, etc. The resistors are each shorted out through an open switch, which is significantly larger than, for example, 10 microns. In this way, the resistor ladder can be adjusted in a binary fashion by, for example, 50 ohm increments by turning on and off respective switches associated with each of the resistors. In these structures, the resistor trim design results into large trim-step-size variability and thereby may be detrimental to (RM) Read-Margin window and overall functional yield.

### SUMMARY

In an aspect of the disclosure, a structure comprising: a set of resistors each of which comprise an increasing resistance value; and a set of switches each of which are connected to a respective resistor of the set of resistors and each of which comprise a decreasing width dimension for each resistor of increasing resistance value.

In an aspect of the disclosure, a structure comprises: a set of resistors, wherein each resistor of the set of resistors connects in series and comprises an increasing resistance value compared to an immediately adjacent resistor; and a set of switches, wherein each switch connects to a respective resistor of the set of resistors and each switch has a decreasing width dimension as a resistance value of each resistor increases.

In an aspect of the disclosure, a structure comprises: a first set of resistors; a second set of resistors connecting in series to a first end of the first set of resistors; a third set of resistors connecting in series to a second end of the first set of resistors; a first set of switches comprising individual switches connecting to respective resistors of the first set of resistors; a second set of switches comprising individual switches connecting to respective resistors of the second set of resistors; and a third set of switches comprising individual switches connecting to respective resistors of the third set of resistors, wherein the individual switches of the first, second and third set of switches connecting to the respective resistors of the first, second and third set of resistors comprise a decreasing width with an increasing resistance value of the respective resistors.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a resistor trimming structure in accordance with aspects of the present disclosure.

FIG. 2 shows a resistor trimming structure in accordance with additional aspects of the present disclosure.

FIG. 3 shows a resistor trimming structure in accordance with further aspects of the present disclosure.

FIG. 4 shows a graph resistance vs. trim setting using the resistor trimming structure of FIGS. 1-3.

### DETAILED DESCRIPTION

The present disclosure relates to semiconductor structures and, more particularly, to resistor trimming structures and methods of use. The resistor trimming structures include an inverse sizing arrangement of resistors versus switches. This configuration will achieve an intended equivalent resistance for each trim element in a trimmable resistor ladder structure. Moreover, the resistor trimming structures may comprise an arrangement of a fully or partial mirroring arrangement for the trim ladder elements (e.g., resistor and switches) to achieve inherent compensation and thereby uniform resistor step sizing for every trim step of a trimmable resistor ladder structure. Advantageously, the resistor trimming structures provide improved read-margin (RM), timing performance and yield, while minimizing any penalties to area and power in an MRAM application. In addition, the resistor trimming circuits provide a uniform and precise resistor trim step sizing having widespread applicability by being process, technology and application independent. For example, the resistor trimming structures may be used in VREF generators or charge pump trimming in any given technology node.

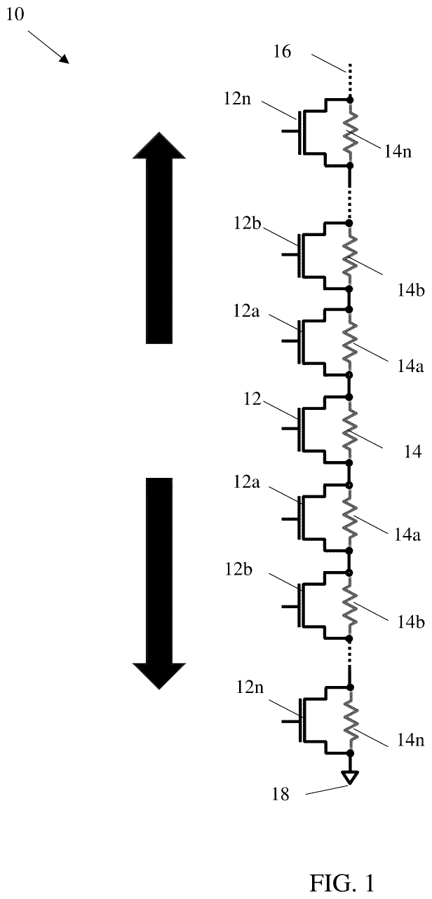

FIG. 1 shows a resistor trimming structure in accordance with aspects of the present disclosure. In the structure 10 of FIG. 1, a plurality of resistors 14, 14a, 14b. . . 14n are arranged in series, each of which are connected to a respective switch 12, 12a, 12b. . . 12n. The resistors 14, 14a, 14b. . . 14n are connected between an input 16 and an output 18. In the arrangement shown, the resistors 14, 14a, 14b. . . 14n and respective switches 12, 12a, 12b. . . 12n are provided in a mirrored fashion, with resistor 14 being a middle resistors and resistors 14a, 14b. . . 14n connected in series with the middle resistor 14 starting from both ends of the middle resistor 14 in increasing resistance value. Accordingly, the resistors in a first set of resistors from the middle resistor 14 and the resistors in a second set of resistors from the middle resistor 14 are equal in numbers (e.g., mirrored). As in each of the embodiments, the switches 12, 12a, 12b. . . 12n may be conventional transistors each which have a respective width dependent on the resistance of the respective resistors 14a, 14b. . . 14n. For example, as the resistance increases for each of the resistors 14a, 14b. . . 14n, each of the widths of the respective switches 12a, 12b, . . . 12n will decrease.

In embodiments, the middle resistor 14 has a resistive value of R0=2⁰×R_{B}, where R_{B} may be a base resistance value of a particular design. By way of an illustrative and non-limiting example, R_{B}=50 Ohms. The resistor 14a may have a value of R₁=(2¹×R_{B})/2. So, for example, should R_{B}=50 Ohms, the resistor 14a would have a value of R₁=50 Ohms. Similarly, the resistor 14b may have a value of R₂=(2²×R_{B})/2. So, for example, should R_{B}=50 Ohms, the resistor 14b would have a value of R₂=100 Ohms. Similarly, the resistor 14n may have a value of Rn=(2ⁿ×R_{B})/2. So, for example, should R_{B}=50 Ohms and the resistor 14n is a third resistor (R₃) in the series, the resistor value of R₃ would be R₃=(2³×R_{B})/2 or R₃=200 Ohms, etc.

Still referring to FIG. 1, it should also be understood that the resistance value and the size, e.g., width, of each of the switches 12a, 12b. . . 12n will have an inverse relationship. For example, as the resistance value increases, the width values of the switches 12a, 12b. . . 12n will decrease. For example, as each resistance value increases by 2×, the respective width value of each of the switches 12a, 12b. . . 12n will be reduced by ½ (from a width of a preceding switch). Mathematically, for example, the width of each switch would be W=(2*W₀)/2ⁿ, where n represents the number of the transistor (or resistor) in the series. By way of example, should the first switch 12a have a width of 64 microns, the second switch 12b would have a width of 32 microns and the third switch 12n would have a width of 16 microns.

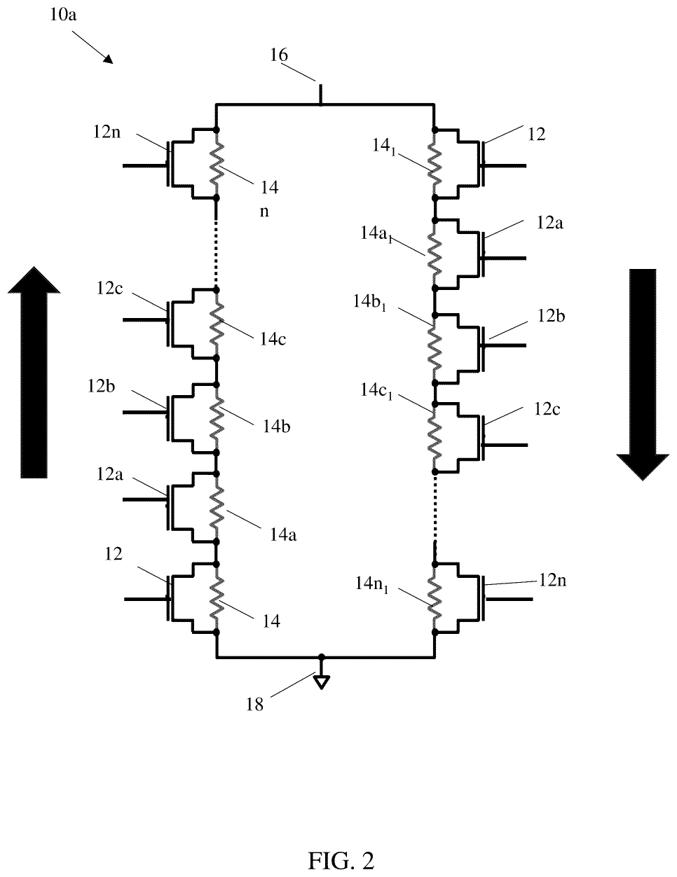

FIG. 2 shows a resistor trimming structure in accordance with additional aspects of the present disclosure. In the structure 10a of FIG. 2, a plurality of resistors 14, 14a, 14b. . . 14n are arranged in series, each connected to a respective switch 12, 12a, 12b. . . 12n. The resistors 14, 14a, 14b, . . . 14n are also connected to the resistors 14₁, 14a₁, 14b₁. . . 14n₁ in parallel. As noted in FIG. 2, the resistors 14₁, 14a₁, 14b₁. . . 14n₁ are also connected in series, in a reverse order from the resistors 14, 14a, 14b. . . 14n. Accordingly, in the arrangement shown in FIG. 2, the resistors 14, 14a, 14b. . . 14n and the resistors 14₁, 14a₁, 14b₁. . . 14n₁ are connected in a reversed mirrored fashion between an input 16 and an output 18. The resistors 14₁, 14a₁, 14b₁. . . 14n₁ are also each connected to a respective switch 12, 12a, 12b. . . 12n.

In embodiments, the resistors 14 and 14₁ have a resistive value of R0=2⁰×R_{B}, where R_{B} may be a base resistance value of a particular design. By way of an illustrative and non-limiting example, when R_{B}=50, the resistor resistors 14 and 14₁ may have a value of 50 Ohms. The resistors 14a and 14a₁ may have a value of R₁=2¹×R_{B}. So, for example, should R_{B}=50 Ohms, the resistors 14a and 14a₁ would have a value of R₁=100 Ohms. Similarly, the resistors 14b and 14b₁ may have a value of R₂=2²×R_{B}. So, for example, should R_{B}=50 Ohms, the resistors 14b and 14b₁ would have a value of R₂=200 Ohms. Similarly, the resistors 14n and 14n₁ may have a value of Rn=2ⁿ×R_{B}. So, for example, should R_{B}=50 Ohms and the resistors 14n and 14n₁ are a third resistor (R₃) in the series, the resistor value of R₃ would be R₃=2³×R_{B} or R₃=400 Ohms, etc.

Still referring to FIG. 2, it should also be understood that the resistance value and the size, e.g., width, of each of the switches 12, 12a, 12b. . . 12n will have an inverse relationship. For example, as the resistance value increases, the width values of the switches 12, 12a, 12b. . . 12n will decrease. By way of example, the switch 12 may have a width, W=32 microns, and switch 12a would have a width of 16 microns, switch 12b would have a width of 8 microns, switch 12c would have a width of 4 microns and switch 12n would have a width W=W₀/2ⁿ, where W₀ is the width of the switch 12 (e.g., W=W₀/2⁰) and n is equal to the corresponding number of the resistor. So, for example, should the switch 12n be associated with the fourth resistor and W=64 microns, the width of the transistor 12n would be 3.125 microns.

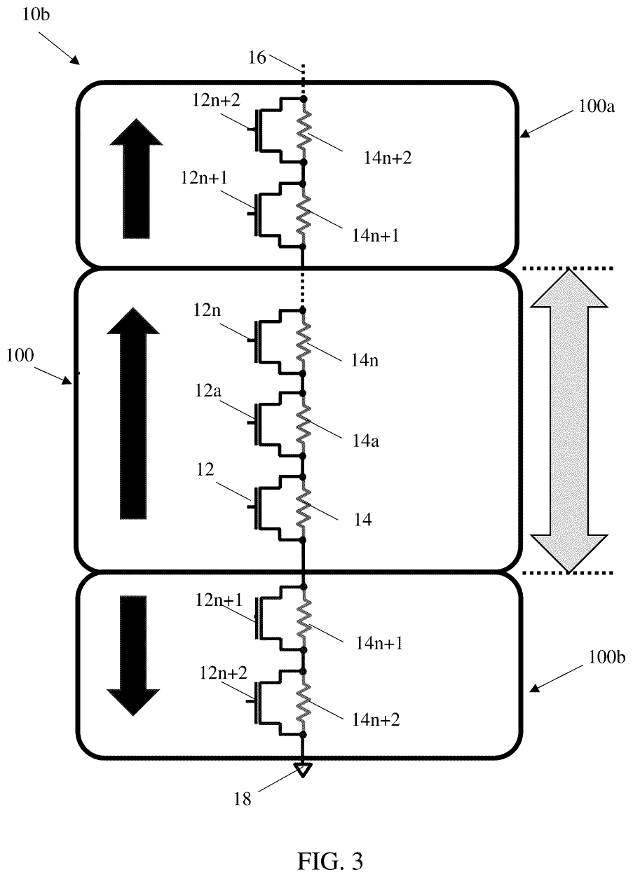

FIG. 3 shows a resistor trimming structure in accordance with further aspects of the present disclosure. In the structure 10b of FIG. 3, a set of resistors 100a, 100b are arranged in series with a common set of resistors 100. In this arrangement, the set of resistors 100a, 100b are on respective ends of the set of resistors 100. The set of resistors 100, 100a, 100b are arranged in series between an input 16 and an output 18. Also, in this arrangement, the set of resistors 100a, 100b comprise the same resistors, e.g., resistor values, and are partially mirrored about the set of resistors 100. As with the other embodiments, each of the resistors of the set of resistors 100, 100a, 100b are connected to a respective switch (e.g., transistor).

More specifically, in the arrangement of FIG. 3, the set of resistors 100 includes resistors 14, 14a. . . 14n, in series, and each of which are connected to a respective switch 12, 12a. . . 12n. As in each of the embodiments, “n” represents an additional number of continuing resistors and/or switches in series. In embodiments, the resistors 14, 14a. . . 14n may have a value of increasing resistance and the switches 12, 12a. . . 12n have a value of decreasing width. More particularly, the resistors 14, 14a. . . 14n may have a resistance value of 2X from its preceding resistor and the switches 12, 12a. . . 12n may have a width of ½ from a width of the preceding switch.

By way of example, should resistor 14 have a resistance of R0=2⁰×R_{B}, resistor 14a would have a resistance of R1=2¹×R_{B} and resistor 14n would have a resistance of Rn=2ⁿ×R_{B}. Accordingly, and by way of non-limiting example, should resistor 14 have a resistance of 50 Ohms, resistor 14a would have a resistance of 100 Ohms and should resistor 14n be the third resistor in the series of resistors, it would have a resistance of 200 Ohms, etc. Similarly, and by way of non-limiting example, should switch 12 have a width of W=32 microns, switch 12a would have a width of 16 microns and switch 12n would have a width of 8 microns (e.g., W=W₀/2ⁿ), etc.

Still referring to FIG. 3, the set of resistors 100a, 100b each include resistors 14n+1 and 14n+2, in series, each of which are connected to a respective switch 12n+1 and 12n+2. Similar to the set of resistors 100, the resistors 14n+1, 14n+2, may have a value of increasing resistance of 2X from a previous resistor value and the width of the switches 12n+1, 12n+2 may have a decreasing width of half (e.g., ½) from a width of a previous transistor. By way of example and using the values from the set of resistors 100, the switch 12n+1 may have a width of 4 microns and switch 12n+2 may have a width of 2 microns, etc. Similarly, using the values from the set of resistors 100, the resistor 14n+1 would have a value of 400 Ohms and the resistor 14n+2 would have a value of 200 Ohms, etc. Accordingly, the resistor values would be Rn+1=(2ⁿ⁺¹×RB)/2 and Rn+2=(2ⁿ⁺²×RB)/2.

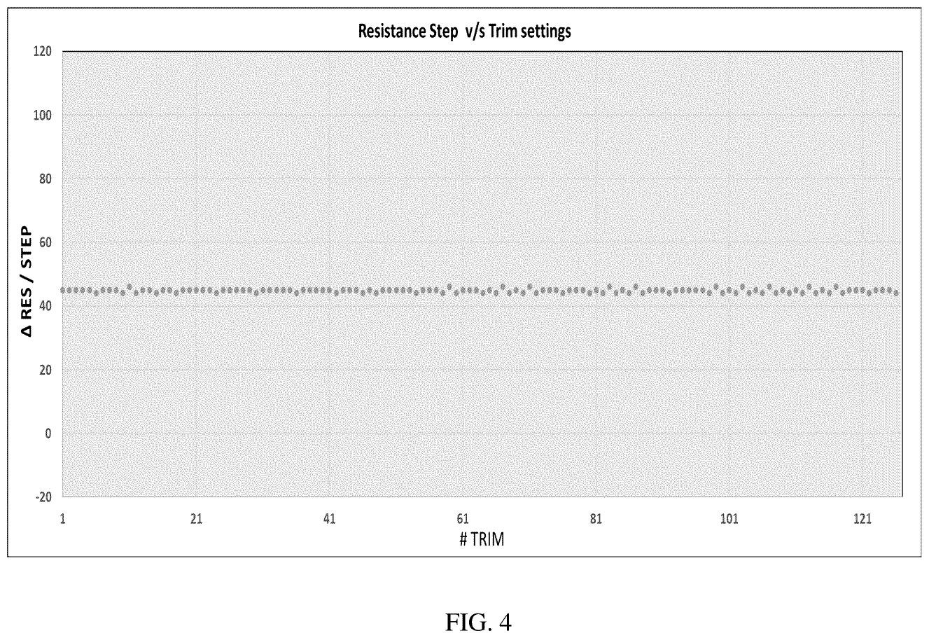

FIG. 4 shows a graph resistance vs. trim setting using the resistor trimming structure of FIGS. 1-3. More specifically, the x-axis of FIG. 4 represents a number of resistors (e.g., number of trims) and the y-axis of FIG. 4 represents a number of steps or difference in resistive values. As shown in FIG. 4, for example, by implementing the structures shown in FIGS. 1-3, it is now possible to obtain uniform trim over a wide range of trim settings. As shown, for example, in FIG. 4, a minimum/maximum deviation is about +/−1 Ohm.

The resistor trimming structures of the present disclosure can be manufactured in a number of ways using a number of different tools. In general, though, the methodologies and tools are used to form structures with dimensions in the micrometer and nanometer scale. The methodologies, i.e., technologies, employed to manufacture the resistor trimming structures of the present disclosure have been adopted from integrated circuit (IC) technology. For example, the structures are built on wafers and are realized in films of material patterned by photolithographic processes on the top of a wafer. In particular, the fabrication of the resistor trimming structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

The resistor trimming structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) and structures as described above are used in integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a set of resistors each of which comprise an increasing resistance value; and
a set of switches each of which are connected to a respective resistor of the set of resistors and each of which comprise a decreasing width dimension for each resistor of increasing resistance value.

2. The structure of claim 1, wherein the set of resistors are connected in series between an input and an output.

3. The structure of claim 2, wherein the set of resistors comprise a first set of resistors and a second set of resistors arranged in a mirrored fashion such that each next resistor of the first and second set of set of resistors have an increasing resistance value starting from each end of the middle resistor and each switch connected to a next resistor comprises a corresponding decrease in width from an immediately preceding switch.

4. The structure of claim 3, wherein the increase in resistance value comprises 2× from an immediately preceding resistor and the corresponding decrease in width of each switch is one-half.

5. The structure of claim 3, wherein the resistors in the first set of resistors and the resistors of the second set of resistors are equal in number.

6. The structure of claim 1, wherein the set of resistors comprise a first set of resistors connected in parallel to a second set of resistors, wherein each resistor of the first set of resistors and the second set of resistors is connected in series.

7. The structure of claim 6, wherein the first set of resistors are in an inverse order of the second set of resistors.

8. The structure of claim 7, wherein:
the resistors of the first set of resistors are each connected to a respective switch with a decrease in width corresponding to an increase in resistance value of the resistors of the first set of resistors; and
the resistors of the second set of resistors are each connected to a respective switch with an increase in width corresponding to a decrease in resistance value of the resistors of the second set of resistors.

9. The structure of claim 1, wherein the set of resistors comprise, in series, a first set of resistors, a second set of resistors and a third set of resistors, the first set of resistors are common to both the second set of resistors and the third set of resistors, with the second set of resistors and the third set of resistors being mirrored.

10. The structure of claim 9, wherein the second set of resistors and the third set of resistors comprise resistors of an increasing resistance value starting from the connection to the first set of resistors.

11. The structure of claim 10, wherein the switches connecting to the resistors of the second set of resistors and the third set of resistors comprise a decreasing width as the resistors of the second set of resistors and the third set of resistors have increase in resistance value.

12. A structure comprising:
a set of resistors, wherein each resistor of the set of resistors connects in series and comprises an increasing resistance value compared to an immediately adjacent resistor; and
a set of switches, wherein each switch connects to a respective resistor of the set of resistors and each switch has a decreasing width dimension as the resistance value of each resistor increases.

13. The structure of claim 12, wherein the set of resistors are in a mirrored arrangement, with each next resistor from a middle resistor outwards comprising the increased resistance value and each switch connected to each next resistor having a decrease in width.

14. The structure of claim 12, wherein the set of resistors comprising a first set of resistors and a second set of resistors connected in parallel, the first set of resistors comprising resistors with resistance values in an inverse order from resistors of the second set of resistors.

15. The structure of claim 12, wherein the set of resistors comprises a first set of resistors, a second set of resistors and a third set of resistors connected in series, and the set of switches comprises a first set of switches, a second set of switches and a third set of switches, wherein each switch of the first, second and third set of switches connect to a respective resistor of the first, second and third set of resistors.

16. The structure of claim 15, wherein the second set of resistors and the second set of switches are mirrored to the third set of resistors and the third set of switches.

17. The structure of claim 16, wherein the first set of resistors comprise resistors in series starting from a lowest resistance value to a highest resistance value, a first resistor of the second set of resistors connects in series to the resistor with the highest resistance value and a first resistor of the third set of resistors connect in series to the resistor with the lowest resistance value.

18. The structure of claim 17, wherein the first resistor of the second and third set of resistors comprises a resistance value higher than the highest resistance value of the first set of resistors and a first switch of the second and third set of switches connecting to the first resistor second and third set of resistors comprises a width smaller than a width of a switch connecting to the resistor with the highest resistance value of the first set of resistors.

19. A structure comprising:
a first set of resistors;
a second set of resistors connecting in series to a first end of the first set of resistors;
a third set of resistors connecting in series to a second end of the first set of resistors;
a first set of switches comprising individual switches connecting to respective resistors of the first set of resistors;
a second set of switches comprising individual switches connecting to respective resistors of the second set of resistors; and
a third set of switches comprising individual switches connecting to respective resistors of the third set of resistors,
wherein the individual switches of the first, second and third set of switches connecting to the respective resistors of the first, second and third set of resistors comprise a decreasing width with an increasing resistance value of the respective resistors.

20. The structure of claim 19, wherein the individual switches of the second set of switches and the third set of switches and the respective resistors of the second and third set of resistors are mirrored.
